(19) United States
(12) Patent Application Publication
(10) Pub. No.: US 2010/0019379 A1
(43) Pub. Date: Jan. 28, 2010

(54) EXTERNAL HEAT SINK FOR BARE-DIE FLIP CHIP PACKAGES

(75) Inventors: Sam Ziqun Zhao, Irvine, CA (US); Calvin Wong, Irvine, CA (US)

Correspondence Address: FIALA & WEAVER, P.L.L.C.;C/O CPA GLOBAL, P.O. BOX 52050, MINNEAPOLIS, MN, 55402, US

(73) Assignee: BROADCOM CORPORATION, Irvine, CA (US)

(21) Appl. No.: 12/261,407

(22) Filed: Oct. 30, 2008

Related U.S. Application Data
(60) Provisional application No. 61/083,225, filed on Jul. 24, 2008.

(51) Int. Cl. H01L 23/36; H01L 21/98

(52) U.S. Cl. 257/713; 438/122; 257/E21.705; 257/E23.101

(57) ABSTRACT

An integrated circuit package includes a substrate having opposing first and second surfaces, a flip chip integrated circuit die, and a heat sink. A first surface of die is mounted to the first surface of the substrate by a plurality of electrically conductive solder bumps. The heat sink has a first surface that includes a recessed region extending along a length of the heat sink in the first surface and that includes first and second supporting portions separated by the recessed region. The first and second supporting portions are attached to the first surface of the substrate such that the die is positioned in the recessed region. A second surface of the die is attached to a surface of the recessed region.

This application claims the benefit of U.S. Provisional Application No. 61/083,225, filed on Jul. 24, 2008, which is incorporated by reference herein in its entirety.

### BACKGROUND OF THE INVENTION

1. Field of the Invention

The present invention relates to integrated circuit packaging technology, and more particularly to flip chip integrated circuit package substrates.

2. Background Art

Integrated circuit (IC) chips or dies from semiconductor wafers are typically interfaced with other circuits using a package that can be attached to a printed circuit board (PCB). One such type of IC die package is a ball grid array (BGA) package. BGA packages provide for smaller footprints than many other package solutions available today. A BGA package has an array of solder ball pads located on a bottom external surface of a package substrate. Solder balls are attached to the solder ball pads. The solder balls are reflowed to attach the package to the PCB.

In some BGA packages, a die is attached to the substrate of the package (e.g., using an adhesive), and signals of the die are interfaced with electrical features (e.g., bond fingers) of the substrate using wire bonds. In such a BGA package, wire bonds are connected between signal pads/terminals of the die and electrical features of the substrate. In another type of BGA package, which may be referred to as a “flip chip package,” a die may be attached to the substrate of the package in a “flip chip” orientation. In such a BGA package, solder bumps are formed on the signal pads/terminals of the die, and the die is inverted (“flipped”) and attached to the substrate by reflowing the solder bumps so that they attach to corresponding pads on the surface of the substrate.

The dies in integrated circuit packages, such as BGA packages, typically generate a great amount of heat during operation. Thus, BGA packages are frequently configured to disperse the generated heat so that their operation is not adversely affected by the generated heat. For example, an external heat sink may be attached to a BGA package to disperse heat from the BGA package. External heat sinks are effective solutions to improving the thermal performance of a package. However, in the case of flip chip BGA packages, the package geometry creates additional complexities in the mounting of such heat sinks.

For instance, most existing external heat sinks utilize a solid base plate design that is completely flat on the bottom surface. The flat base plate surface serves as an interface between the heat sink and the package, and can be used reliably on plastic BGA packages and flip-chip BGA packages that already have a heat spreader “lid” included. Complications arise when the external heat sink is mounted on a bare die flip-chip package, in which the relatively large external heat sink rests solely on the relatively small silicon die of the package. This creates a high amount of stress on the die, which may lead to damage to the die or the interconnect between the die and the flip chip substrate, rendering the package useless. In such a configuration, stability is another problem. Because the heat sink only has support in the center, the heat sink can easily be dislodged if a moment is applied. Conventional solutions for these problems increase an overall cost such that a flip chip BGA-plus-heat spreader (e.g., a BGA package that has a heat spreader lid attached) package becomes a more cost-efficient option than a bare die flip chip BGA package.

### BRIEF SUMMARY OF THE INVENTION

Integrated circuit packages, heat sinks, and methods and systems for assembling the same are provided.

In one implementation, an integrated circuit package includes a substrate having opposing first and second surfaces, a flip chip integrated circuit die, and a heat sink. A first surface of the die is mounted to the first surface of the substrate by a plurality of electrically conductive solder bumps. The heat sink has a first surface that includes a recessed region extending along a length of the heat sink in the first surface and that includes first and second supporting portions separated by the recessed region. The first and second supporting portions are attached to the first surface of the substrate such that the die is positioned in the recessed region. A second surface of the die is attached to a surface of the recessed region.

In another implementation, an integrated circuit package includes a substrate having opposing first and second surfaces, a flip chip integrated circuit die, and a heat sink. The flip chip integrated circuit die has opposing first and second surfaces. The first surface of the die is mounted to the first surface of the substrate by a plurality of electrically conductive solder bumps. The heat sink has a first surface that includes a first post extending from a first corner of the first surface of the heat sink, a second post extending from a second corner of the first surface of the heat sink, a third post extending from a third corner of the first surface of the heat sink, and a fourth post extending from a fourth corner of the first surface of the heat sink. The first, second, third, and fourth posts are attached to the first surface of the substrate such that the die is positioned within a perimeter formed by the first, second, third, and fourth posts, and the second surface of the die is attached to the first surface of the heat sink.

In another implementation, a method for assembling integrated circuit packages is provided. A stock material is extruded through an extrusion die to form a heat sink strip having a cross-section defined by the extrusion die. The extruding includes forming a recessed region in a first surface of the heat sink strip that extends along a length of the heat sink strip, and forming a plurality of fins in a second surface of the heat sink strip along the length of the heat sink strip. The heat sink strip is cross-cut to separate the heat sink strip into a plurality of heat sinks.

In still another implementation, a system for assembling integrated circuit packages is provided. The system includes an extrusion press and a cross-cutter. The extrusion press is configured to extrude a stock material through an extrusion die to form a heat sink strip having a cross-section defined by the extrusion die. The extrusion die is configured to form a recessed region in a first surface of the heat sink strip along a length of the heat sink strip, and to form a plurality of fins in a second surface of the heat sink strip along the length of the heat sink strip. The cross-cutter is configured to cross-cut the heat sink strip to separate the heat sink strip into a plurality of heat sinks.

These and other objects, advantages and features will become readily apparent in view of the following detailed description of the invention. Note that the Summary and Abstract sections may set forth one or more, but not all exemplary embodiments of the present invention as contemplated by the inventor(s).

### BRIEF DESCRIPTION OF THE DRAWINGS/FIGURES

The accompanying drawings, which are incorporated herein and form a part of the specification, illustrate the present invention and, together with the description, further serve to explain the principles of the invention and to enable a person skilled in the pertinent art to make and use the invention.

FIG. 1 shows a cross-sectional side view of an example flip chip BGA package.

FIGS. 2 and 3 show views of surfaces of the substrate of the flip chip BGA package of FIG. 1.

FIGS. 4-14 show views of various conventional flip chip BGA packages and BGA package-heat sink combinations.

FIG. 15 shows a flip chip BGA package with heat sink, according to an example embodiment of the present invention.

FIGS. 16A-16D show various views of an example heat sink, according to an example embodiment of the present invention.

FIG. 17 shows a side view of an example heat sink, according to an example embodiment of the present invention.

FIGS. 18A-18D show various views of an example heat sink, according to an example embodiment of the present invention.

FIGS. 19A-19D show various views of an example heat sink, according to an example embodiment of the present invention.

FIG. 20 shows a flip chip BGA package with heat sink, according to an example embodiment of the present invention.

FIG. 21 shows an example heat sink, according to an embodiment of the present invention.

FIG. 22 shows a system for forming heat sinks, according to an example embodiment of the present invention.

FIG. 23 shows a flowchart for a process for forming heat sinks, according to an example embodiment of the present invention.

FIG. 24 shows an example extrusion die, according to an embodiment of the present invention.

FIGS. 25-31 show example heat sinks, according to embodiments of the present invention.

FIG. 32 shows an integrated packaging assembly system, according to an example embodiment of the present invention.

The present invention will now be described with reference to the accompanying drawings. In the drawings, like reference numbers indicate identical or functionally similar elements. Additionally, the left-most digit(s) of a reference number identifies the drawing in which the reference number first appears.

### DETAILED DESCRIPTION OF THE INVENTION

### Introduction

The present specification discloses one or more embodiments that incorporate the features of the invention. The disclosed embodiment(s) merely exemplify the invention. The scope of the invention is not limited to the disclosed embodiment(s). The invention is defined by the claims appended hereto.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

Furthermore, it should be understood that spatial descriptions (e.g., “above,” “below,” “up,” “left,” “right,” “down,” “top,” “bottom,” “vertical,” “horizontal,” etc.) used herein are for purposes of illustration only, and that practical implementations of the structures described herein can be spatially arranged in any orientation or manner.

### Example Integrated Circuit Packages

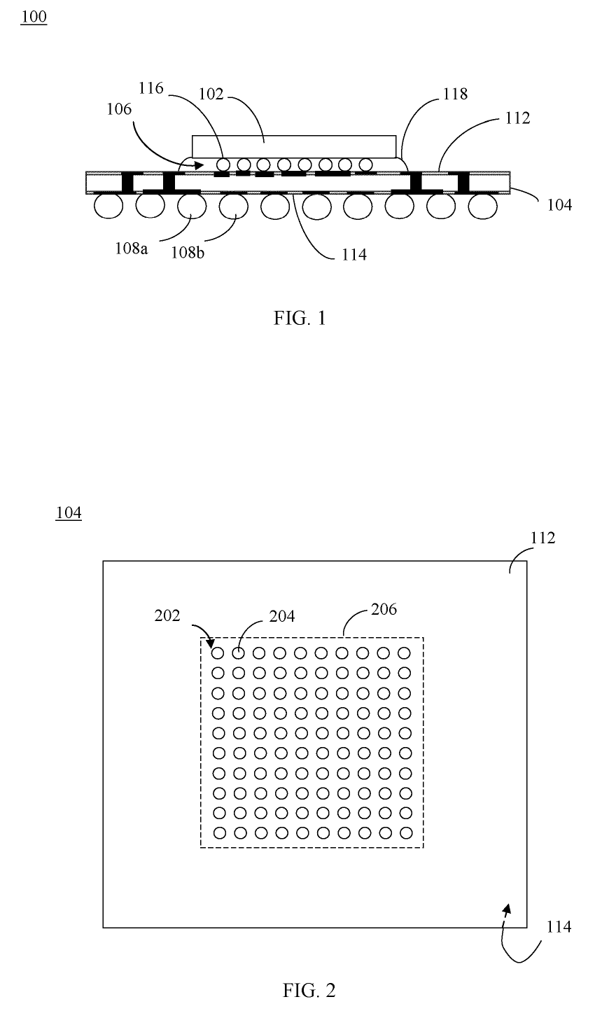

Example integrated circuit packages are described in this section. FIG. 1 shows a cross-sectional view of an example flip chip BGA package 100. Flip chip BGA package 100 may be a plastic BGA (PBGA) package, a flex BGA package, a ceramic BGA package, or other type of BGA package. Flip chip BGA package 100 includes an integrated circuit die/chip 102, a substrate 104, a plurality of solder bumps/balls 106, a plurality of solder balls 108, and an underfill material 118. Substrate 104 has a first (e.g., top) surface 112 that is opposed to a second (e.g., bottom) surface 114 of substrate 104.

Substrate 104 may include one or more electrically conductive layers (such as at first surface 112) that are separated by one or more electrically insulating layers. An electrically conductive layer may include traces/routing, bond fingers, contact pads, and/or other electrically conductive features. For example, BGA substrates having one electrically conductive layer, two electrically conductive layers, or four electrically conductive layers are common. The electrically conductive layers may be made from an electrically conductive material, such as a metal or combination of metals/alloy, including copper, aluminum, tin, nickel, gold, silver, etc. In embodiments, substrate 104 may be rigid or may be flexible (e.g., a “flex” substrate). The electrically insulating layer(s) may be made from ceramic, plastic, tape, and/or other suitable materials. For example, the electrically insulating layer(s) of substrate 104 may be made from an organic material such as BT (bismaleimide triazine) laminate/resin, a flexible tape material such as polyimide, a flame retardant fiberglass composite substrate board material (e.g., FR-4), etc. The electrically conductive and non-conductive layers can be stacked and laminated together, or otherwise attached to each other, to form substrate 104, in a manner as would be known to persons skilled in the relevant art(s).

As shown in FIG. 1, die 102 is attached to substrate 104 in a “flip chip” manner. Solder bumps 106 or any other electrically conductive feature (e.g., solder balls, etc.) are formed on the signal pads/terminals of die 102. Die 102 is attached to substrate 104 in an inverted (“flipped”) orientation with respect to the attachment of dies in wire bond BGA package configurations. Die 102 is attached to substrate 104 by reflowing solder bumps 106 so that solder bumps 106 attach to corresponding pads on (top) surface 112 of substrate 104. FIG. 2 shows a view of surface 112 of substrate 104. As shown in FIG. 2, surface 112 of substrate 104 has a mounting region 206 for a flip chip die, such as die 102. Mounting region 206 includes an array 202 of solder ball/bump pads corresponding to solder bumps 106. In the example of FIG. 2, array 202 includes a ten by ten array of pads 204. However, any number of pads 204 may be present in mounting region 206, depending on the number of solder bumps 106 on the flip chip die to be mounted thereto. When die 102 is mounted to mounting region 206 of substrate 104, solder bumps 106 attach to pads of array 202 on substrate 204. For example, a solder bump/ball 116 shown in FIG. 1 may attach to solder ball/bump pad 204 shown in FIG. 2 when die 102 is mounted to substrate 104.

Underfill material 118 may be optionally present, as shown in FIG. 1. Underfill material 118 fills in a space between die 102 and substrate 104 between solder bumps 106. Underfill material 118 may be an epoxy or any other suitable type of underfill material, as would be known to persons skilled in the relevant art(s).

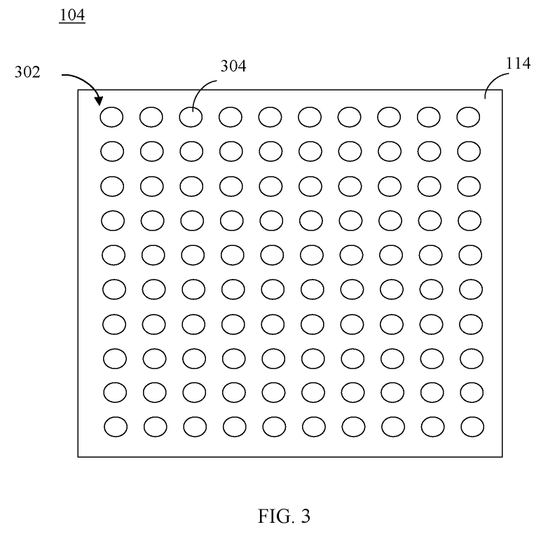

A plurality of solder balls 108 (including solder balls 108a and 108b indicated in FIG. 1) is attached to second surface 114 of substrate 104. FIG. 3 shows a view of second surface 114 of substrate 104. Solder balls 108 are not shown in FIG. 3. Instead, in FIG. 3, second surface 114 of substrate 104 includes an array 302 of solder balls pads 304. In the example of FIG. 3, array 302 includes one hundred solder ball pads 304 arranged in a 10 by 10 array. In other implementations, array 302 may include fewer or greater numbers of solder ball pads 304 arranged in any number of rows and columns. Solder ball pads 304 are attachment locations for solder balls 108 (shown in FIG. 1) on package 100. Solder ball pads 304 are electrically coupled through substrate 104 (e.g., by electrically conductive vias and/or routing) to the electrically conductive features (e.g., traces, bond fingers, contact regions, etc.) of first surface 112 of substrate 104 to enable signals of die 102 to be electrically connected to solder balls 108 through substrate 104. Note that FIG. 3 shows a full array of solder ball pads 304. In some embodiments, array 302 of solder ball pads 304 may be missing some pads 304, so that array 302 is not necessarily a full array of solder balls 108 on second surface 114.

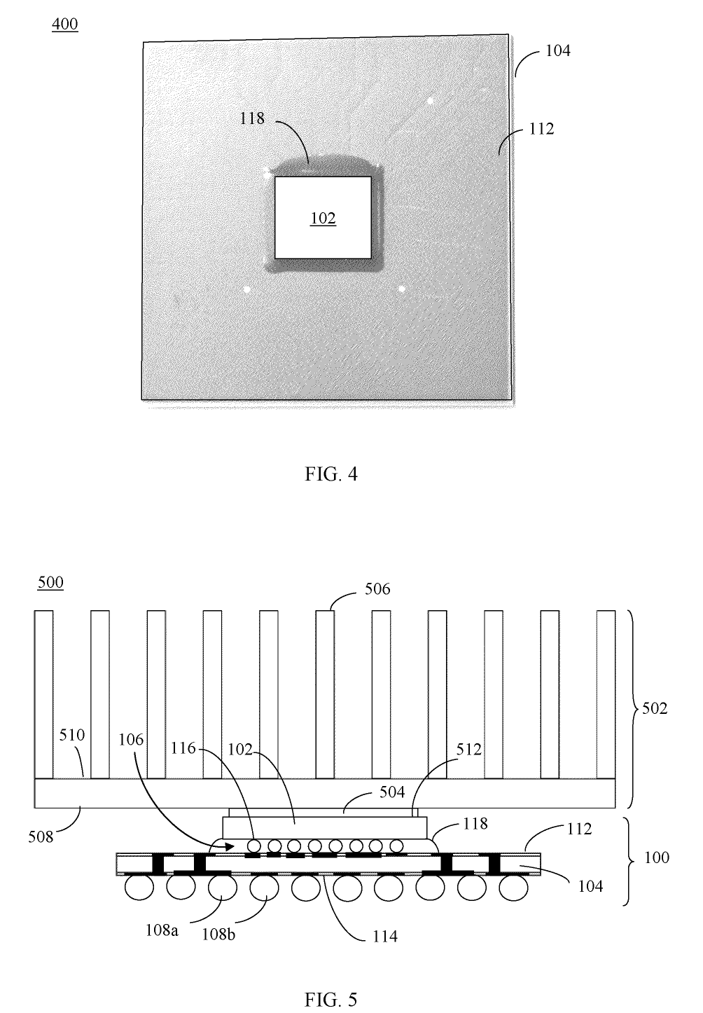

FIG. 4 shows an image of a top view of a flip chip BGA package 400 similar to package 100. Surface 112 of package 400 is shown in FIG. 4. Die 102 is shown in FIG. 4 as mounted to surface 112 in a flip chip manner. Underfill material 118 is visible in FIG. 4 around a perimeter of die 102. Similarly to package 100 shown in FIG. 1, package 400 does not include a heat spreader. Furthermore, die 102 is exposed (e.g., is not covered by an encapsulating material).

FIG. 5 shows a side cross-sectional view of an example flip chip BGA package 500 which is a combination of package 100 shown in FIG. 1 and a heat sink 502. As shown in FIG. 5, heat sink 502 has a planar portion having opposing first and second surfaces 508 and 510. Second surface 510 of heat sink 502 has a plurality of fins 506 extending therefrom. As shown in FIG. 5, first surface 508 of heat sink 502 is attached to a top surface 512 of die 102 by an adhesive material 504. Adhesive material 504 may be a thermal interface material, for example.

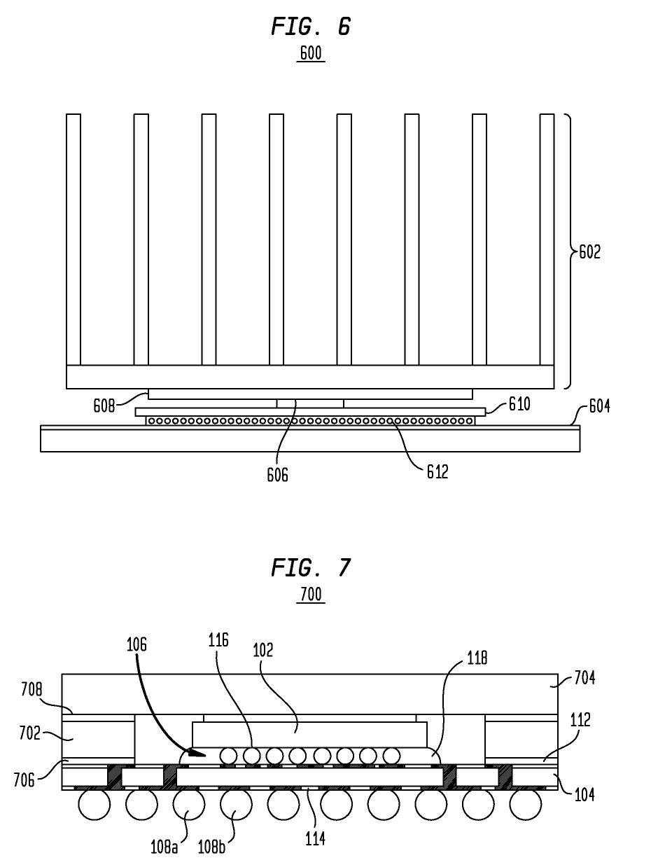

FIG. 6 shows a side view of a flip chip package 600 that includes a heat sink 602, similar to package 500 shown in FIG. 5. As shown in FIG. 6, package 600 includes a flip chip die 606 attached to a substrate 610. Heat sink 602 is mounted to flip chip die 606 by an adhesive material 608. Package 600 is shown mounted to a circuit board 604 by a plurality of solder balls 612.

Packages 500 and 600 shown in FIGS. 5 and 6 have some benefits, including a relatively low package cost. However, packages 500 and 600 of FIGS. 5 and 6 have numerous disadvantages. For example, as shown in FIG. 5, the top surface of die 102 provides a relatively small area of support for heat sink 502. As a result, heat sink 502 may be required to be additionally attached to the circuit board to which package 500 mounted (e.g., the circuit board in FIG. 6) according to a complex mechanical attachment configuration, which leads to a greater heat sink cost and requires additional circuit board real estate for the attachment of heat sink 502 to the circuit board. Package 600 shown in FIG. 5 has the same problem, with heat sink 602 likely needing to be attached to circuit board 604 in a complex manner (not shown in FIG. 6) because of the lack of support received from die 606. The package configurations of FIGS. 5 and 6 lead to a higher overall system cost, and may lead to unwanted mechanical issues due to a complex heat sink attachment configuration needed to stabilize the heat sinks. Such a package configuration may lead to damage to the dies, including die corner “chip-off,” and/or other damage due to the required handling and rework.

FIG. 7 shows a side cross-sectional view of an example flip chip BGA package 700 similar to package 100 shown in FIG. 1, with the addition of a stiffener ring 702 and a heat spreader plate 704. Stiffener ring 702 is mounted to surface 112 of substrate 104 by an adhesive material 706. Stiffener ring 702 surrounds die 102 on substrate 104 in a rectangular ring. Heat spreader plate 704 is mounted to stiffener ring 702 by an adhesive material 708. Heat spreader 704 and stiffener ring 702 form an enclosure for die 102 on substrate 104.

FIG. 8 shows a side cross-sectional view of an example flip chip BGA package 800 similar to package 100 shown in FIG. 1, with the addition of a lid 802. Lid 802 includes a recessed portion 806 surrounded on all sides by a perimeter rim portion 808. Lid 802 may be circular or rectangular in shape (e.g., when viewed from the top down in FIG. 8). Rim portion 808 is attached to surface 112 of substrate 104 by an adhesive material 804, such that die 102 is enclosed in a cavity 810 within recessed portion 806. Lid 802 forms an enclosure for die 102 on substrate 104.

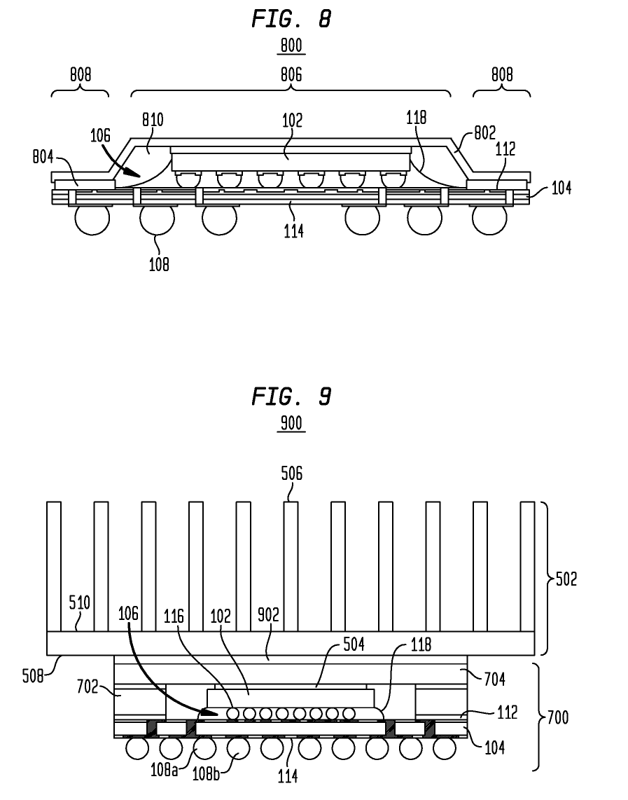

FIG. 9 shows a side cross-sectional view of an example flip chip BGA package 900, which is a combination of package 700 shown in FIG. 7 and heat sink 502. As shown in FIG. 9, first surface 508 of heat sink 502 is attached to a top surface 902 of heat spreader plate 704 by adhesive material 504.

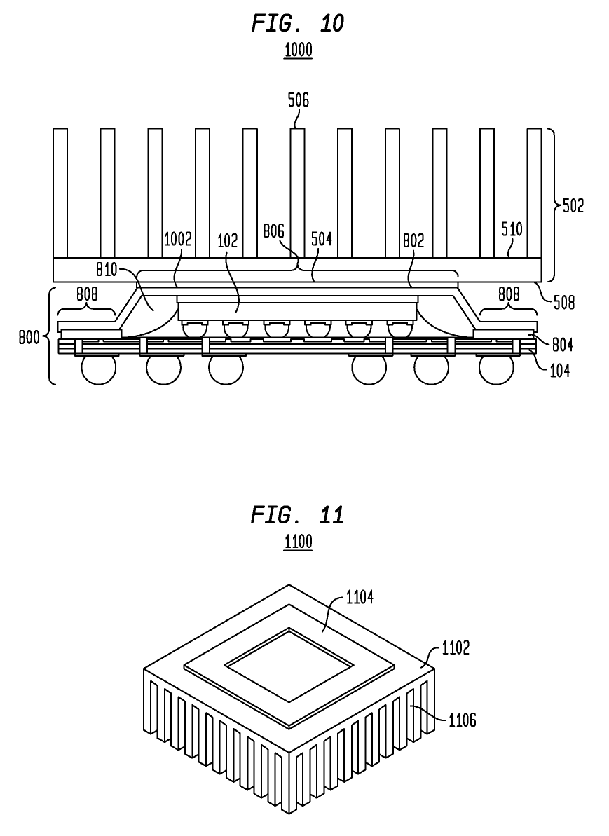

FIG. 10 shows a side cross-sectional view of an example flip chip BGA package 1000, which is a combination of package 800 shown in FIG. 8 and heat sink 502. As shown in FIG. 10, first surface 508 of heat sink 502 is attached to a top surface 1002 of recessed portion 806 of lid 802 by adhesive material 504.

Packages 900 and 1000 have some benefits. For example, packages 900 and 1000 exhibit relatively good thermal performance. Relatively large heat sinks can be mounted to heat spreader plate 704 (shown in FIG. 9) and lid 802 (shown in FIG. 10) with greater stability than with regard to the package configurations of FIGS. 5 and 6. Relatively lower cost heat sinks may be attached to heat spreader plate 704 and lid 802, and additional circuit board real estate is not needed for the heat sink (in contrast to package 600 shown in FIG. 6). An overall package-heat sink cost is lower for packages 900 and 1000, and greater flexibility with respect to applications and system designs is provided. However, packages 900 and 1000 have disadvantages, including a higher package cost (e.g., the cost of packages 700 and 800, respectively).

FIG. 11 shows a perspective view of a heat sink 1100. Heat sink 1100 is an example of heat sink 502. FIG. 11 shows a first surface 1102 of heat sink 1100 (corresponding to first surface 508 of heat sink 502) that may be attached to a BGA package. A second surface of heat sink 1100 (not visible in FIG. 11) has a plurality of fins 1106 extending therefrom. As shown in FIG. 11, a ring gasket 1104 is attached (e.g., epoxied, taped, etc.) to first surface 1102. Ring gasket 1104 may provide a pliable interface between heat sink 1100 and a BGA package when heat sink 1100 is mounted to the BGA package.

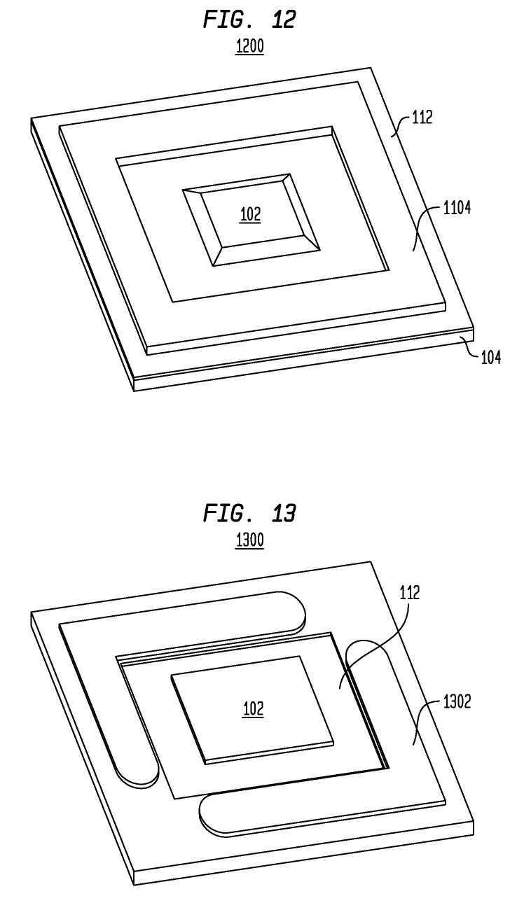

FIG. 12 shows a perspective view of a flip chip BGA package 1200, similar to BGA package 100 shown in FIG. 1. FIG. 12 shows surface 112 of substrate 104 of BGA package 1200, which may attach a heat sink (e.g., heat sink 502). As shown in FIG. 11, ring gasket 1104 is attached (e.g., epoxied, taped, etc.) to surface 112.

Ring gasket 1104 is a soft, adhesive ring gasket which may be used to prevent the external heat sink (e.g., heat sink 502) from rocking back and forth when the heat sink is mounted on a bare die 102 (e.g., as shown in FIGS. 5 and 6). Ring gasket 1104 also absorbs some of the load applied by the heat sink, reducing the risk of mechanical failure on die 102. Ring gasket 1104 may be provided in sheets of ring gaskets, and can be applied to either the package (as shown in FIG. 12) or the heat sink (as shown in FIG. 11). Ring gasket 1104 is made of a soft, foam material, and therefore can be readily applied to dies of varying thicknesses without clearance problems. However, ring gasket 1104 adds an additional cost to the BGA package because ring gasket 1104 is typically purchased separately from the heat sink. Additionally, ring gasket 1104 typically has adhesive only on one side, creating a weak interface between the heat sink and the BGA package. Because ring gasket 1104 is soft/pliable, it provides only limited support to the heat sink. Vibration and shock stresses induced by the heat sink during transportation, handling, and application will be concentrated on the exposed flip chip die 102 (e.g., shown in FIGS. 4 and 12) and are not transferred/cushioned to the flip chip substrate 112 (e.g., shown in FIGS. 4 and 12) effectively.

FIG. 13 shows a perspective view of a flip chip BGA package 1300 that is similar to BGA package 100 shown in FIG. 1, with the addition of a stiffener ring 1302. Stiffener ring 1302 (e.g., stiffener ring 702 in FIG. 7) is attached to surface 112 of substrate 104 of BGA package 1300. A surface of a heat sink (e.g., heat sink 502) may be attached to stiffener ring 702 to be mounted to package 1300.

Stiffener ring 1302, which may be copper, for example, has a thickness generally equal to a combined thickness of die 102 and bumps 106 (e.g., as shown in FIG. 1). Stiffener ring 1302 creates a large, flat surface for an external heat sink to be mounted. As such, stiffener ring 1302 provides for relatively high mechanical stability, but adds a substantial cost to the overall price of BGA package 1300. Also, stiffener ring 1302 is typically added to package 1300 during an assembly process taking place at a package assembly house. Thus, customers that request package 1300 are effectively committed to a particular heat sink solution for their product (e.g., a stiffener ring and heat sink combination).

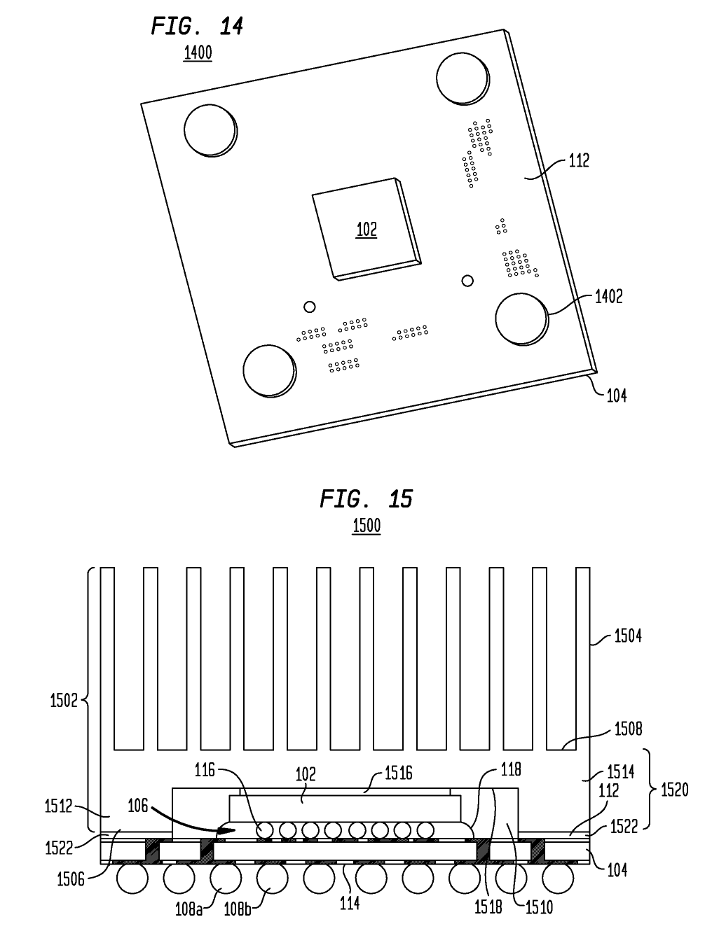

FIG. 14 shows a perspective view of a flip chip BGA package 1400 that is similar to BGA package 100 shown in FIG. 1, with the addition of four circular studs 1402. Studs 1402 are attached to surface 112 of substrate 104 of BGA package 1300. Studs 1402 are formed separately from substrate 104. A stud 1402 is attached to surface 112 near each corner of surface 112. A surface of a heat sink (e.g., surface 508 of heat sink 502 shown in FIG. 5) may be attached to studs 1402 to be mounted to package 1400.

Studs 1402 provide additional support when mounting an external heat sink (e.g., heat sink 502 shown in FIG. 5) to package 1400 by providing multiple points of contact between package 1400 and the heat sink. Thus, studs 1402 increase package stability and reliability in a similar manner as does ring gasket 1104 shown in FIGS. 11 and 12. Studs 1402 are frequently used in processor chips because studs 1402 leave space for other electrical components, such as capacitors, to be placed on surface 112 of substrate 104. A disadvantage of studs 1402 is an additional cost in the manufacturing and mounting of studs 1402. Unlike ring gasket 1104, due to manufacturing constraints, studs 1402 are typically applied on substrate 104 (as shown in FIG. 14) rather than on the heat sink (as shown in FIG. 11 for heat sink 1100).

Example embodiments are described in the following section that overcome deficiencies of the flip chip BGA package and heat sink configurations described above.

### EXAMPLE EMBODIMENTS

The example embodiments described herein are provided for illustrative purposes, and are not limiting. Although described below with reference to BGA packages, the examples described herein may be adapted to other types of integrated circuit packages. Including pin grid array (PGA) (e.g., a package having pins for package mounting), land grid array (LGA) (e.g., a package having pads for package mounting), and further types of integrated circuit packages that include one or more dies mounted to a substrate. Furthermore, additional structural and operational embodiments, including modifications/alterations, will become apparent to persons skilled in the relevant art(s) from the teachings herein.

Extrusion and cross-cut extrusion external heat sinks for bare-die flip-chip BGA applications are provided. External heat sinks improve the thermal performance of a flip chip BGA packages. However, the geometry of bare-die flip-chip BGA packages creates additional complexities in the mounting of such heat sinks. Embodiments for heat sinks and BGA packages described herein avoid such complexities without causing significant additional cost. In an embodiment, a heat sink base plate portion includes a recessed region that encloses the die on a package substrate. Both the top of the die and the top of the substrate may be in contact with the base plate portion of the heat sink, creating a stable structure that provides high thermal performance.

To overcome reliability, stability, and/or cost issues in mounting an external heat sink to a bare-die flip-chip BGA package, instead of using a base plate having a planar bottom surface, the base plate is manufactured to have a recessed region near or at the center of the base plate along the length of the base plate. The recessed region may have a height/depth that is substantially the same as the height of a die (plus underfill bumps). An example of a typical recessed region height provided for illustrative purposes may be 0.85 mm, or the recessed region may have any other suitable height. Such a base plate provides mechanical advantages, including a support structure that meets the substrate near the edges of the heat sink, and a recessed region to meet the height of the die near the center of the heat sink. A groove-like or bridge-like structure is created over the die that allows the heat sink to be in contact with the package at the substrate and the die. Such a configuration may be referred to as a “grooved heat sink” or “bridged heat sink.”

The size of the recessed region in the heat sink may be selected based on the particular heat sink application. For example, the recessed region size may be selected to be larger than a size of the die to be enclosed in the recessed region. In an embodiment, the width of the package equal to or wider than the distance between the outer edges of the heat sink support structures (the edges of the heat sink on either side of the recessed region). In another embodiment, the width of the package may be less than the distance between the outer edges of the heat sink support structures.

In an embodiment, a heat sink is configured to accommodate packages having a footprint equal to or greater than an area of the heat sink. In another embodiment, a heat sink is configured to be securely mounted on packages that have a footprint that may be smaller than an area of the heat sink. In further embodiments, a configuration of the heat sink directs airflow to the die. For example, air may be able to flow through the package by flowing over the substrate, along the sides of the die through the groove formed by the heat sink.

In an embodiment, extrusion or cross-cut extrusion manufacturing techniques may be used to manufacture heat sinks. A bridge shape of a heat sink base plate can be formed during an extrusion process, in which the bridge shaped feature will be included in the heat sink forming die (a die used for extrusion—“extrusion die”—not to be confused with the package semiconductor die). Cost-effective manufacturing processes that are already in place may be taken advantage of so that additional steps to the heat sink forming process are not needed.

As compared to flip chip BGA packages having external heat sinks (without heat sink mounts), such as shown in FIGS. 5 and 6, grooved heat sink embodiments provide advantages. For instance, a grooved heat sink enables an external heat sink to be mounted to bare-die flip chip BGA packages in a secure manner. Mechanical problems described above with respect to FIGS. 5 and 6, such as instability and movement of the heat sink, are resolved using a grooved heat sink. In embodiments, stress between the heat sink and the die is reduced by the coupling of multiple supports of the heat sink with the substrate. Mechanical reliability is improved for package applications and/or for package transportation environments that result in vibration and/or shock stresses to packages. The heat sink supports also reduce the force applied to the package die by the heat sink, reducing problems such as die corner chip off and/or other forms of damage to the die caused by conventional heat sinks.

As compared to flip chip BGA packages having external heat sinks, grooved heat sink embodiments provide advantages. For example, a bridged heat sink offers similar mechanical advantages to the heat sink mounting solutions described above with respect to FIGS. 7-14 relative to the “heat sink only” alternative (e.g., FIGS. 5 and 6). Furthermore, the bridged heat sink provides advantages in cost and assembly. The configurations described above require additional materials and/or additional processes for heat sink mounting (e.g., complex circuit board attachment mechanisms for BGA packages 500 and 600 of FIGS. 5 and 6, stiffener ring 702 for BGA packages 700 and 900 of FIGS. 7 and 9, a heat spreader lid for BGA packages 800 and 1000 of FIGS. 8 and 10, a ring gasket 1104 for BGA package 1200 of FIG. 12, a stiffener ring 1302 for BGA package 1300 of FIG. 13, and studs 1402 for BGA package 1400 of FIG. 14), and thus are relatively expensive. After a bridged heat sink is formed, the bridged heat sink can be directly mounted to a BGA package using available thermal interface materials used to interface conventional external heat sinks with a BGA package. In effect, bridged heat sinks may be manufactured in a manner that does not add additional costs or steps to the BGA package manufacturing process.

Various example embodiments of bridged heat sinks are described in further detail below.

For example, FIG. 15 shows a side cross-sectional view of an example flip chip BGA package 1500, according to an example embodiment of the present invention. As shown in FIG. 15, BGA package 1500 is similar to package 100 shown in FIG. 1, with the addition of a heat sink 1502. Heat sink 1502 is an example “grooved” heat sink, according to an embodiment. As shown in FIG. 15, heat sink 1502 has a base plate portion 1520 having opposing first and second surfaces 1506 and 1508. Base plate portion 1520 has a recessed region 1510 in first surface 1506 between a first supporting portion 1512 and a second supporting portion 1514 of base plate portion 1520. As shown in FIG. 15, an inner surface 1518 of recessed region 1510 is attached to a top surface of die 102 by an adhesive material 1516. Adhesive material 1516 may be any type of adhesive material, such as an epoxy, a thermal interface material, an electrically conductive adhesive material (e.g., including metal particle-filled epoxy, such as silver flakes filled epoxies, etc.) an electrically non-conductive material, or other type of adhesive material, conventionally available or proprietary. First supporting portion 1512, recessed region 1510 in first surface 1506 of heat sink 1500, and second supporting portion 1514 form a “bridge” over die 102. First supporting portion 1512 is attached to surface 112 (of substrate 104) and second supporting portion 1512 is attached to surface 112 by an adhesive material 1522. Adhesive material 1512 is optional, and when present may be any suitable adhesive material, including being the same as adhesive material 1516 or a different adhesive material. Second surface 1508 of heat sink 1502 has a plurality of fins 1504 extending therefrom. Any number of fins 1504 may be present. In the embodiment of FIG. 15, heat sink 1502, including base plate portion 1520 (including first and second supporting portions 1512 and 1514) and fins 1504, forms a single piece unit.

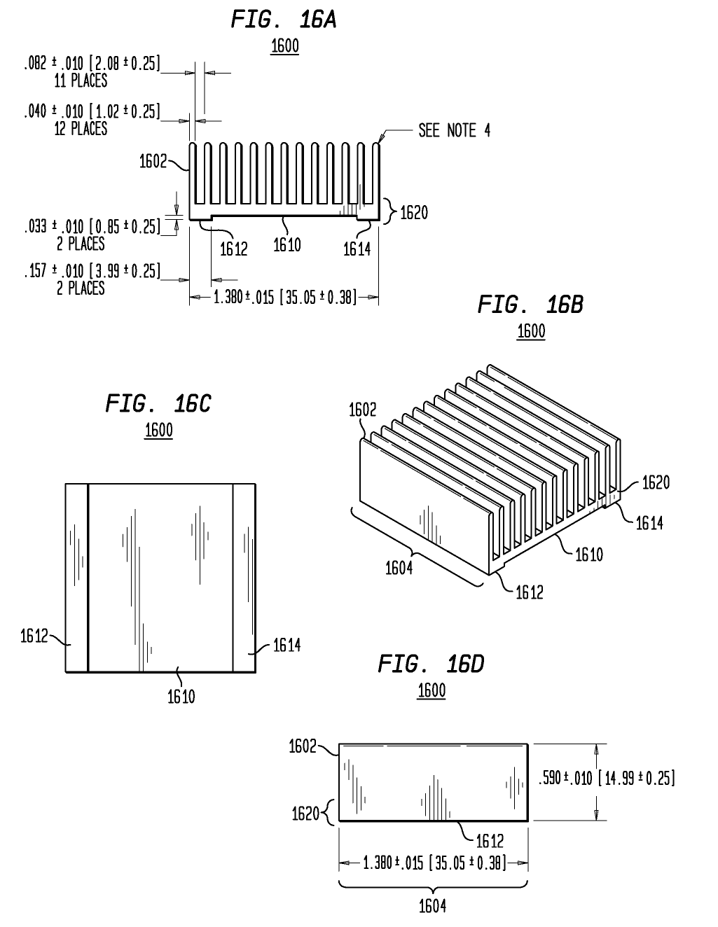

FIGS. 16A-16D show various views of an example heat sink 1600, according to an example embodiment of the present invention. FIG. 16A shows a side view of heat sink 1600, where fins 1602 are viewed edge-on. FIG. 16B shows a perspective view of heat sink 1600. FIG. 16C shows a bottom view of heat sink 1600. FIG. 16D shows a side view of heat sink 1600, where a side of a fin 1602 is viewed. Heat sink 1600 is generally the same as heat sink 1502 shown in FIG. 15. Heat sink 1602 is an example “bridged” heat sink, according to an embodiment. As shown in FIGS. 16A-16D, heat sink 1600 has a base plate portion 1620 having opposing first and second surfaces. Base plate portion 1620 has a recessed region 1610 in the first surface between a first supporting portion 1612 and a second supporting portion 1614 of base plate portion 1620. First supporting portion 1612, recessed region 1610 in the first surface, and second supporting portion 1614 form a “bridge” that is configured to extend over a die of a BGA package to which heat sink 1600 may be mounted (in a similar manner as shown for heat sink 1502 in FIG. 15). The inner surface of recessed region 1610 may be in contact with a top surface of the die (e.g., directly or through an adhesive material). The second surface of base plate portion 1620 of heat sink 1600 has a plurality of fins 1602 extending therefrom. Any number of fins 1602 may be present. In the embodiment of FIG. 16, heat sink 1600, including base plate portion 1620 (including first and second supporting portions 1612 and 1614) and fins 1602, forms a single piece unit.

Several example dimensions for heat sink 1600 are shown in FIGS. 16A and 16D. As shown in the perspective view of heat sink 1600 in FIG. 16B, fins 1602, supporting portions 1612 and 1614, and recessed region 1610 of heat sink 1600 each have lengths that are equal to a length 1604 of heat sink 1600.

FIG. 17 shows a side view of an example heat sink 1700, according to an example embodiment of the present invention. Heat sink 1700 is generally the same as heat sink 1502 shown in FIG. 15. Several example dimensions for heat sink 1700 are shown in FIG. 17. For instance, a fin spacing 1702, a fin thickness 1704, a heat sink height 1706, a base plate inner thickness 1708, a recessed region depth 1710, a supporting portion width, 1712 and a heat sink width 1714 are all indicated in FIG. 17. In one embodiment, these dimensions may have the following example values: fin spacing 1702 equal to 2.1 mm, fin thickness 1704 equal to 1.0 mm, heat sink height 1706 equal to 15.0 mm, base plate inner thickness 1708 equal to 2.5 mm, recessed region depth 1710 equal to 0.85 mm, supporting portion width 1712 equal to 4.0 mm, and heat sink width 1714 equal to 35.0 mm.

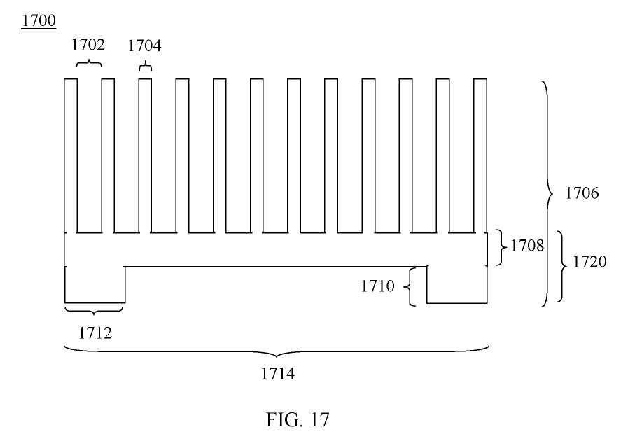

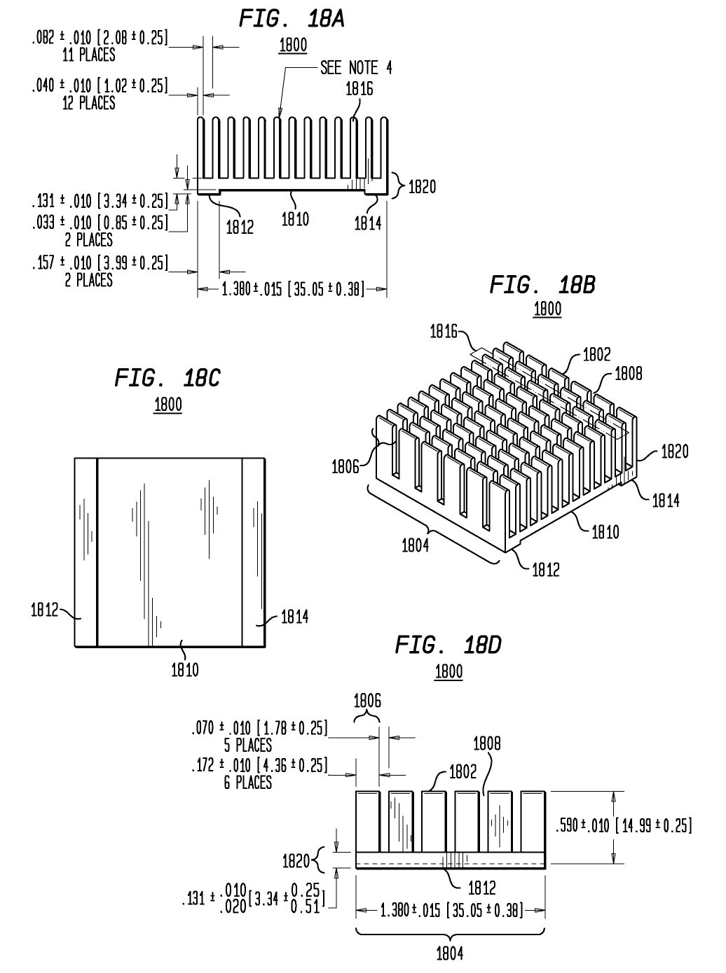

FIGS. 18A-18D show various views of an example heat sink 1800, according to an example embodiment of the present invention. FIG. 18A shows a side view of heat sink 1800, where fins 1802 are viewed edge-on. FIG. 18B shows a perspective view of heat sink 1800. FIG. 18C shows a bottom view of heat sink 1800. FIG. 18D shows a side view of heat sink 1800, where a side of a fin 1802 is viewed. Heat sink 1800 is generally the same as heat sink 1800 shown in FIG. 16, with differences described below. Heat sink 1802 is an example “bridged” heat sink, according to an embodiment. As shown in FIGS. 18A-18D, heat sink 1800 has a base plate portion 1820 having opposing first and second surfaces. Base plate portion 1820 has a recessed region 1810 in the first surface between a first supporting portion 1812 and a second supporting portion 1814 of base plate portion 1820. First supporting portion 1812, recessed region 1810 in the first surface, and second supporting portion 1814 form a “bridge” that is configured to extend over a die of a BGA package to which heat sink 1800 may be mounted (in a similar manner as shown for heat sink 1502 in FIG. 15). The inner surface of recessed region 1810 may be in contact with a top surface of the die (e.g., directly or through an adhesive material). The second surface of base plate portion 1820 of heat sink 1800 has a plurality of fins 1802 extending therefrom. Any number of fins 1802 may be present. In the embodiment of FIG. 18, heat sink 1800, including base plate portion 1820 (including first and second supporting portions 1812 and 1814) and fins 1802, forms a single piece unit.

Several example dimensions for heat sink 1800 are shown in FIGS. 18A and 18D. As shown in the perspective view of heat sink 1800 in FIG. 18B, supporting portions 1812 and 1814, and recessed region 1810 of heat sink 1800 each have lengths that are equal to a length 1804 of heat sink 1800. Furthermore, as shown in the perspective view of heat sink 1800 in FIG. 18B, each fin 1802 has a length 1806, which is less than length 1804 of heat sink 1800. Multiple fins 1802 are present in each row 1816 of a plurality of rows 1816 of fins 1802 along a length 1804 of heat sink 1800. In the example of FIGS. 18A-18D, each row 1816 includes six fins 1802. A plurality of cross-cuts 1808 is formed across a width of heat sink 1800 in a top surface of heat sink 1800 to separate each row 1816 into multiple fins 1802.

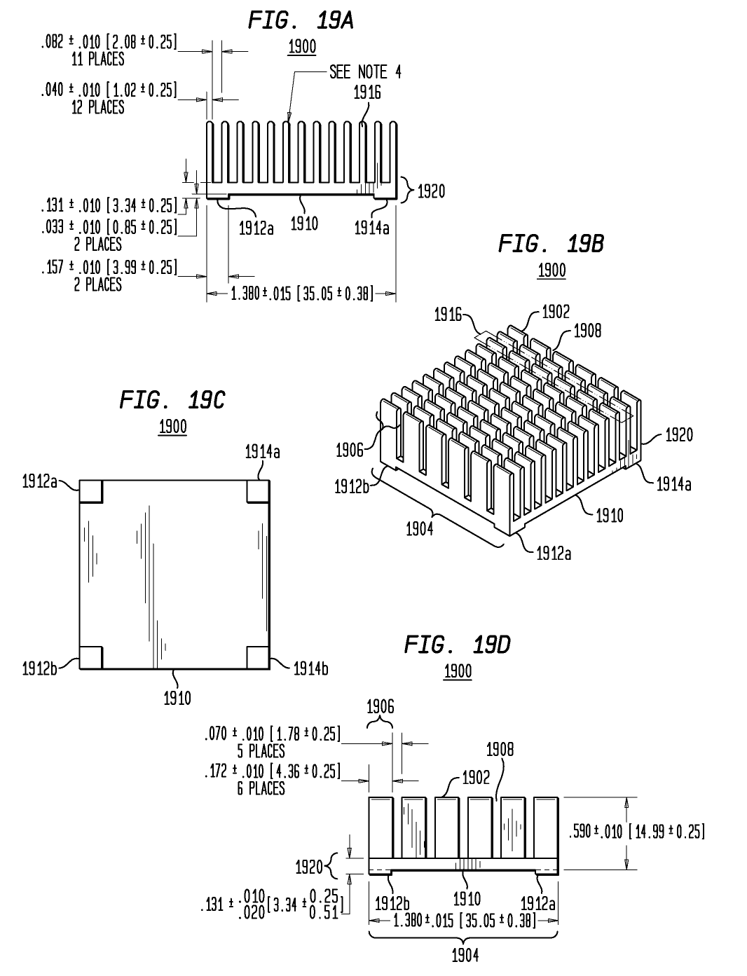

FIGS. 19A-19D show various views of an example heat sink 1900, according to an example embodiment of the present invention. FIG. 19A shows a side view of heat sink 1900, where fins 1902 are viewed edge-on. FIG. 19B shows a perspective view of heat sink 1900. FIG. 19C shows a bottom view of heat sink 1900. FIG. 19D shows a side view of heat sink 1900, where a side of a fin 1902 is viewed. Heat sink 1900 is generally the same as heat sink 1800 shown in FIG. 18, with differences described below. Heat sink 1902 is an example “bridged” heat sink, according to an embodiment. As shown in FIGS. 19A-19D, heat sink 1900 has a base plate portion 1920 having opposing first and second surfaces. Base plate portion 1920 has a recessed region 1910 in the first surface between a first supporting portion 1912 and a second supporting portion 1914 of base plate portion 1920. First supporting portion 1912, recessed region 1910 in the first surface, and second supporting portion 1914 form a “bridge” that is configured to extend over a die of a BGA package to which heat sink 1900 may be mounted (in a similar manner as shown for heat sink 1502 in FIG. 15). The inner surface of recessed region 1910 may be in contact with a top surface of the die (e.g., directly or through an adhesive material). The second surface of base plate portion 1920 of heat sink 1900 has a plurality of fins 1902 extending therefrom. Any number of fins 1902 may be present. In the embodiment of FIG. 19, heat sink 1900, including base plate portion 1920 (including first and second supporting portions 1912 and 1914) and fins 1902, forms a single piece unit.

Several example dimensions for heat sink 1900 are shown in FIGS. 19A and 19D. As shown in the perspective view of heat sink 1900 in FIG. 19, each fin 1902 has a length 1906, which is less than a length 1904 of heat sink 1900. Multiple fins 1902 are present in each row 1916 of a plurality of rows 1916 of fins 1902 along a length 1904 of heat sink 1900. In the example, each row 1916 includes six fins 1902. A plurality of cross-cuts 1908 is formed across a width of heat sink 1900 in a top surface of heat sink 1900 to separate the rows 1916 into multiple fins 1902.

As shown in FIGS. 16A-16D and 18A-18D, heat sinks 1600 and 1800 have cavities 1610 and 1810 respectively in a bottom surface, that respectively separate first and second supporting portions 1612 and 1614 and first and second supporting portions 1812 and 1814. In FIG. 16B, first and second supporting portions 1612 and 1614 have lengths that are equal to length 1604 of heat sink 1600, and in FIG. 18B, first and second supporting portions 1812 and 1814 have lengths that are equal to length 1804 of heat sink 1800. In contrast, in the embodiment of FIGS. 19A-19D, heat sink 1900 has separate corner-located posts 1912a and 1912b on a first edge (corresponding to a first supporting portion, such as first supporting portion 1512 in FIG. 15) on the bottom surface of heat sink 1900. Heat sink 1900 also has separate corner located posts 1914a and 1914b along a second edge (corresponding to a second supporting portion, such as second supporting portion 1514 in FIG. 15) on the bottom surface of heat sink 1900. Posts 1912a, 1912b, 1914a, and 1914b are used to mount heat sink 1900 to a BGA package. In FIG. 15, posts 1912a, 1912b, 1914a, and 1914b are rectangular shaped, but may have other shapes in other embodiments.

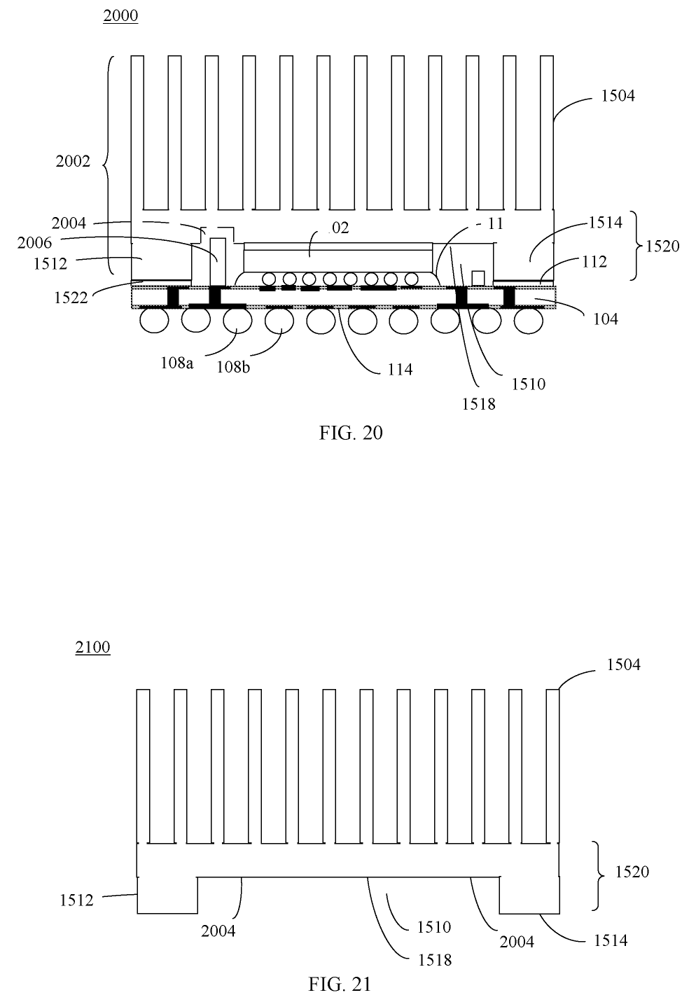

FIG. 20 shows a side cross-sectional view of an example flip chip BGA package 2000, according to an example embodiment of the present invention. As shown in FIG. 20, BGA package 2000 is similar to package 1500 shown in FIG. 15, with differences described as follows. As shown in FIG. 20, package 2000 includes a heat sink 2002. Heat sink 2002 is generally similar to heat sink 1502 shown in FIG. 15, with the addition of a recess, indentation, or cavity 2004 formed in inner surface 1518 of recessed region 1510. Cavity 2004 is formed in recessed region 1510 to provide spacing for a component 2006 (e.g., a capacitor, resistor, inductor, transistor, second integrated circuit chip, etc.) mounted on surface 112 of substrate 104, and enclosed in recessed region 1510 along with die 102. Component 2006 has a height greater than a height of die 102, and thus would collide with the surface of heat sink 2002 in recessed region 1510 if cavity 2004 was not present. Cavity 2004 receives an end of component 2006 so that component 2006 does not collide with heat sink 2002 when heat sink 2002 is mounted to surface 112. The surface of cavity 2004 may or may not contact component 2006 when heat sink 2002 is mounted to surface 112.

Cavity 2004 may have any suitable width and depth configured to accommodate one or more components 2006 mounted to substrate 104. Furthermore, any number of cavities 2004 may be present in heat sink 2002, as required for a particular application. For example, FIG. 21 shows a heat sink 2100, according to an embodiment of the present invention. As shown in FIG. 21, heat sink 2100 is generally similar to heat sink 2002 shown in FIG. 20, with the addition of a second cavity 2004 in inner surface 1518 of recessed region 1510 of heat sink 2100.

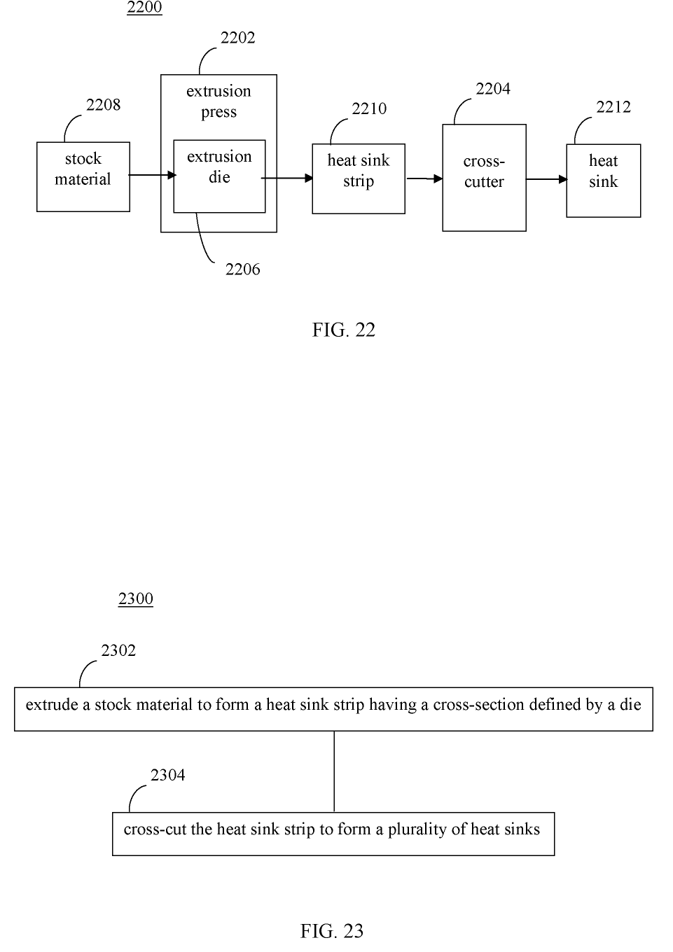

Bridged heat sinks may be formed in a variety of ways, according to embodiments of the present invention. For example, FIG. 22 shows a block diagram of a system 2200 for forming bridged heat sinks. For instance, heat sinks 1502 (FIG. 15), 1600 (FIGS. 16A-16D), 1700 (FIG. 17), 1800 (FIGS. 18A-18D), 1900 (FIGS. 19A-19D), 2002 (FIG. 20), and 2100 (FIG. 21) may be formed according to system 2200. As shown in FIG. 22, system 2200 includes an extrusion press 2202 and a cross-cutter 2204. Furthermore, extrusion press 2202 includes an extrusion die 2206. System 2200 is described as follows with respect to a flowchart 2300 shown in FIG. 23. Flowchart 2300 provides a process for forming heat sinks, according to an example embodiment of the present invention. Flowchart 2300 is described as follows.

As shown in FIG. 23, flowchart 2300 begins with step 2302. In step 2302, a stock material is extruded to form a heat sink strip having a cross-section defined by a die. For example, with reference to FIG. 22, extrusion press 2202 receives a stock material 2208. Stock material 2208 may be any suitable material for heat sinks, including a metal such as copper, aluminum, tin, nickel, gold, silver, or other metal, or a combination of metals/alloy, a ceramic material, a polymer, etc. Extrusion press 2202 includes a press, such as a hydraulic press, an electric press, an oil pressure-based press, or other type of press, configured to force stock material 2208 through die 2206. Stock material 2208 may be heated prior to being provided to extrusion press 2202, or may be extruded while cold. Stock material 2208 may have a rectangular cross-section, or other shape cross-section, when being applied to extrusion press 2202. In one configuration, a dummy block may be positioned behind stock material 2208, and extrusion press 2202 may include a ram that presses on the dummy block to force stock material 2208 through die 2206. Heat sink strip 2210 may be allowed to cool (if heated prior to being extruded).

Forcing stock material 2208 through die 2206 generates a heat sink strip 2210, which has a cross-section defined by die 2206. Thus, extrusion press 2202 may form features in heat sink strip 2210, such as fans (such as fans 1504 shown in FIG. 15), one or more recesses (such as recessed region 1510 shown in FIG. 15), one or more sub-recesses/cavities (such as cavity 2004 shown in FIG. 20), and/or further heat sink features. Examples of such further heat sink features are described elsewhere herein. Such features are formed along a length of heat sink strip 2210 by extrusion press 2202.

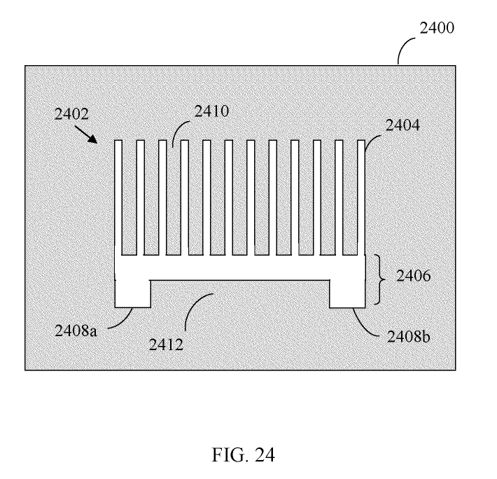

For instance, FIG. 24 shows an example extrusion die 2400, according to an embodiment of the present invention. As shown in FIG. 24, die 2400 includes an opening 2402. Opening 2402 has an outline that defines the cross-sectional shape of a heat sink strip formed by passing a stock material through opening 2402 of die 2400. As shown in FIG. 24, opening 2402 has a plurality of parallel slots 2404 separated by narrow elongated die tabs 2410. Each slot 2404 has an end that opens into a base plate opening region 2406. Base plate opening region 2406 corresponds to base plate portion 1520 (e.g., shown in FIG. 15). Base plate opening region 2406 is generally rectangular, with a rectangular recessed area formed by a relatively short widened tab 2412 that protrudes into base plate opening region 2406. First and second open regions 2408a and 2408b are formed on either side of widened tab 2412 that correspond to first and second supporting portions 1512 and 1514.

In step 2304, the heat sink strip is cross-cut to form a plurality of heat sinks. For example, with reference to FIG. 22, cross-cutter 2204 receives heat sink strip 2210. Cross-cutter 2204 cuts heat sink strip 2210 into a plurality of separate heat sinks. For example, cross-cutter 2204 may include one or more cutting blades (e.g., saw blades) that cut across a width of heat sink strip 2210 to form individual heat sinks, such as heat sink 1600 shown in FIG. 16. Furthermore, in an embodiment, cross-cutter 2204 may include one or more additional cutting blades that cut slots in a surface of heat sink strip 2210 (but do not cut all the way through heat sink strip 2210) to form cross-cuts in the resulting individual heat sinks. For example, cross-cutter 2204 may form cross-cuts 1808 shown in FIG. 18 in a top surface of the heat sink strip 2210 to create rows 1816 of fins 1802. Still further, in an embodiment, cross-cutter 2204 may include one or more blades (e.g., saw blades, milling blades, etc.) that may be used to cut supporting portions extending along a length of heat sink strip 2210 (in a similar fashion to first and second supporting portions 1612 and 1614 shown in FIG. 16) into separate supporting portions, such as posts or stubs. For example, cross-cutter 2204 may operate on heat sink 1800 shown in FIG. 18 (e.g., while heat sink 1800 is still in heat sink strip 2210, or after heat sink 1800 is separated from heat sink strip 2210) to form a gap present between posts 1912a and 1912b and between posts 1914a and 1914b shown in FIG. 19, converting heat sink 1800 to heat sink 1900.

Note that system 2200 of FIG. 22 and flowchart 2300 of FIG. 23 are provided for illustrative purposes, and heat sink embodiments of the present invention may be formed according to alternative systems and processes, including using a molding system/process, a stamping system/process, etc.

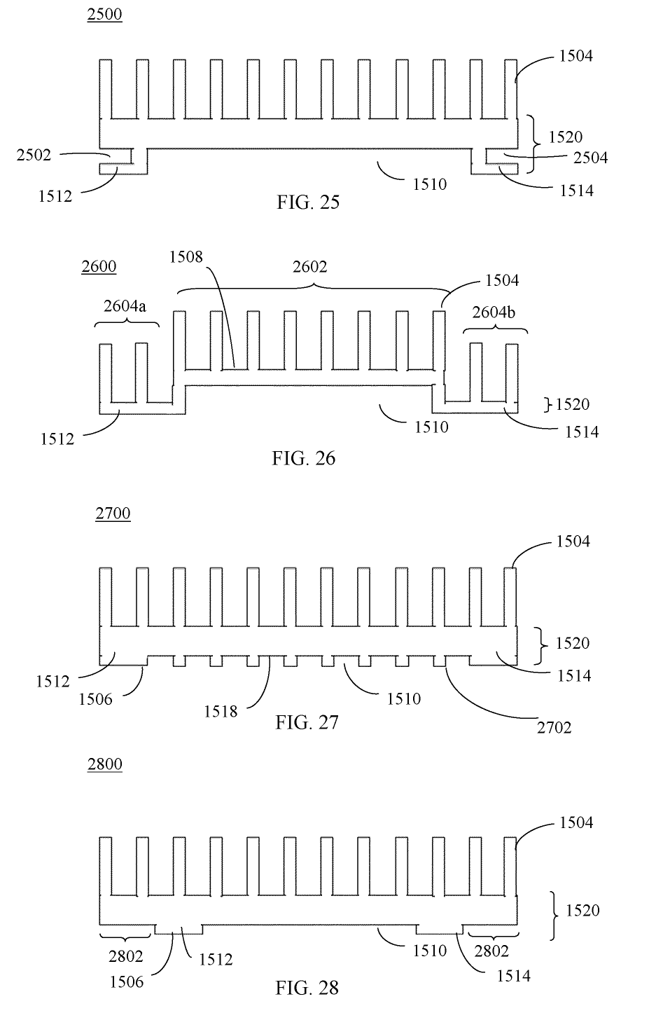

FIGS. 25-31 show further example bridged heat sink embodiments. For example, the bridged heat sinks shown in FIGS. 25-31 may be formed by system 2200 shown in FIG. 22, and according to flowchart 2300 shown in FIG. 23.

FIG. 25 shows a side view of a heat sink 2500 that is similar to heat sink 1502 shown in FIG. 15, with differences described as follows. As shown in FIG. 25, notches 2502 and 2504 are formed in opposing sides of heat sink 2500. Notch 2502 is formed in a first side of heat sink 2500 in first supporting portion 1512, and notch 2504 is formed in a second side of heat sink 2500 in second supporting portion 1514. Notches 2502 and 2504 extend along a length of heat sink 2500 (e.g., length 1604 shown in FIG. 16B for heat sink 1600). For example, notches 2502 and 2504 may be formed by corresponding tabs extending from right and left inner side surfaces of an opening in a die 2206 of extrusion press 2202 (in FIG. 22) that is used to form heat sink 2500, such as opening 2402 in die 2400 shown in FIG. 24.

FIG. 26 shows a side view of a heat sink 2600 that is similar to heat sink 1502 shown in FIG. 15, with differences described as follows. As shown in FIG. 26, fins 1504 extending from a first region 2602 of second surface 1508 opposite recessed region 1510 are offset from fins 1504 extending from second and third regions 2604a and 2604b of second surface 1508 that are respectively opposite first and second supporting portions 1512 and 1514. In FIG. 26, base plate portion 1520 of heat sink 2600 is shown as uniformly thick throughout (rather than base plate portion 1520 being thicker at first and second supporting portions 1512 and 1514 than at recessed region 1510, as in FIG. 15), although in other embodiments, the thickness of base plate portion 1520 may vary. In the embodiment of FIG. 26, first surface 1508 of base plate portion 1520 has a central plateau portion (in first region 2602) opposite recessed region 1510, and has downset planar portions (in second and third regions 2604a and 2604b) on either side of the plateau portion opposite first and second supporting portions 1512 and 1514, respectively. A pair of fins 1504 extends from each of the downset planar portions, and eight fins 1504 extend from the central plateau portion in the example of FIG. 26. Heat sink 2600 may be formed by appropriately shaping a die 2206 of extrusion press 2202 (in FIG. 22) that is used to form heat sink 2600.

FIG. 27 shows a side view of a heat sink 2700 that is similar to heat sink 1502 shown in FIG. 15, with differences described as follows. As shown in FIG. 27, a plurality of fins 2702 is formed in recessed region 1510 that extend from inner surface 1518 of recessed region 1510 in a direction opposite of fins 1504. Similarly to fins 1504, fins 2702 extend along a length of heat sink 2700. Fins 2702 have a height equal to a depth of recessed region 1510. Thus, fins 2702 divide recessed region 1510 into a plurality of trenches formed first surface 1506 of heat sink 2700 along the length of heat sink 2700. For example, fins 2702 may be formed by alternating notches (recesses) and tabs (extending out) in a bottom inner surface of a die 2206 of extrusion press 2202 (in FIG. 22) that is used to form heat sink 2700.

FIG. 28 shows a side view of a heat sink 2800 that is similar to heat sink 1502 shown in FIG. 15, with differences described as follows. As shown in FIG. 28, first and second supporting portions 1512 and 1514 are not located on outermost edges of first surface 1506 of heat sink 2800, and instead are each set inward away from the outermost edges of first surface 1506 of heat sink 2800 by a distance 2802. Thus, first and second supporting portions 1512 and 1514 form a pair of protruding portions extending along a length of the bottom surface of heat sink 2800 separated by recessed region 1510 extending along a length of the bottom surface of heat sink 2800.

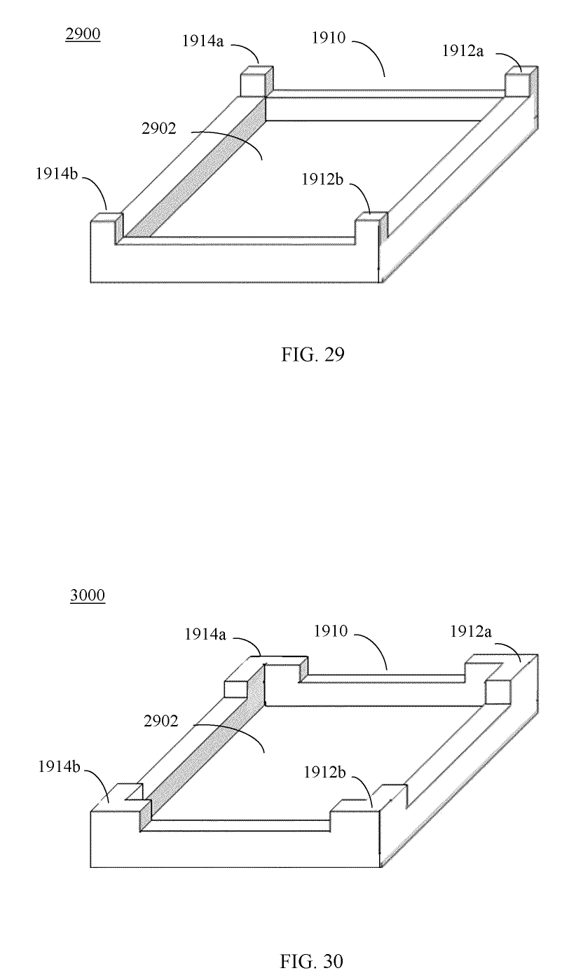

FIGS. 29-31 show example heat sinks that include posts 1912a, 1912b, 1914a, and 1914b to mount the heat sinks to package substrates instead of supporting portions 1512 and 1514. In FIGS. 29-31, fins, which may be present, are not shown for ease of illustration.

FIG. 29 shows a perspective bottom view of a heat sink 2900 similar to heat sink 1900 shown in FIG. 19, with differences described as follows. As shown in FIG. 29, posts 1912a, 1912b, 1914a, and 1914b extend from a bottom surface of heat sink 2900 separated by recessed region 1910. Furthermore, a rectangular cavity 2902 is formed in the bottom surface of heat sink 2900 below recessed region 1910. In embodiments, cavity 2902 may be formed in bottom surface of heat sink 1900 by a routing process, milling process, or other suitable process, after extrusion is performed by extrusion press 2202 (FIG. 22), prior to or after cross-cutting is performed by cross-cutter 2204 on heat sink strip 2210. As shown in FIG. 29, each corner of rectangular cavity 2902 extends up to a respective one of the inner corners of posts 1912a, 1912b, 1914a, and 1914b.

FIG. 30 shows a perspective bottom view of a heat sink 3000 similar to heat sink 2900 shown in FIG. 29, with differences described as follows. As shown in FIG. 30, the corners of rectangular cavity 2902 extend inside the inner corners of posts 1912a, 1912b, 1914a, and 1914b to remove an inner rectangular portion (e.g., form a notch) in each of posts 1912a, 1912b, 1914a, and 1914b.

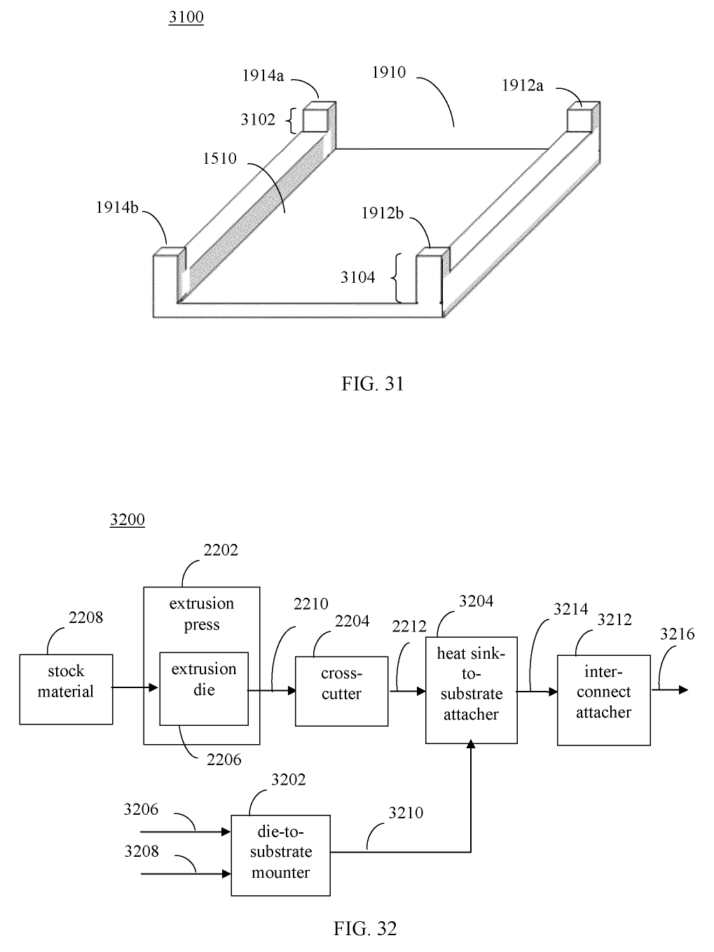

FIG. 31 shows a perspective bottom view of a heat sink 3100 similar to heat sink 1900 shown in FIG. 19, with differences described as follows. As shown in FIG. 31, recessed region 1510 and recessed region 1910 are both formed in the bottom surface of heat sink 3100 such that a combined recessed region in the bottom surface has a first depth 3102 between posts/studs 1912a and 1912b and between posts/studs 1914a and 1914b along the length of heat sink 3100, and has a second depth 3104 between posts/studs 1912a and 1914a and between posts/studs 1912b and 1914b. Second depth 3104 extends along the length of heat sink 3100, being greater than first depth 3102.

Note that system 2200 shown in FIG. 22 for forming bridged heat sinks may be integrated into an integrated circuit packaging assembly system. For example, FIG. 32 shows an integrated packaging assembly system 3200, according to an embodiment of the present invention. As shown in FIG. 32, system 3200 includes extrusion press 2202, cross-cutter 2204, a die-to-substrate mounter 3202, a heat sink-to-substrate attacher 3204, and an interconnect attacher 3212. System 3200 is described as follows.

Die-to-substrate mounter 3202 receives dies 3206 and substrates 3208. Substrates 3208 may be received individually or in the form of a strip of substrates. Die-to-substrate mounter 3202 is configured to perform the step of mounting dies 3206 to substrates 3208. For example, die-to-substrate mounter 3202 may include a pick-and-place machine or other mechanism used to mount individual dies to substrates. Solder bumps and/or solder balls may be reflowed to attach the dies to the substrates in a flip chip manner, and an underfill material may be optionally applied. Die-to-substrate mounter 3202 outputs die-mounted substrates 3210.

As described above, extrusion press 2202 may extrude stock material 2208 to form heat sink strip 2210, according to step 2302 of flowchart 2300 (FIG. 23). Cross-cutter 2204 may receive heat sink strip 2210, and cut heat sink strip 2210 into a plurality of separate heat sinks 2212, according to step 2304 of flowchart 2300.

Heat sink-to-substrate attacher 3204 may receive die-mounted substrates 3210 and heat sinks 2212, and may attach heat sinks 2212 to die-mounted substrates 3210 as described above. For example, heat sink-to-substrate attacher 3204 may include a pick-and-place machine or other mechanism used to mount individual heat sinks to substrates. Heat sink-to-substrate attacher 3204 outputs heat sink and die-mounted substrates 3214.

Interconnect attacher 2210 may receive heat sink and die-mounted substrates 3214, and attach or form solder balls or other electrical interconnect on the substrates, and may output integrated circuit packages 3216.

Note that in another embodiment, if the dies are mounted to a substrate strip by die-to-substrate mounter 3202, the die-mounted substrate strip may be singulated into separate substrates/integrated circuit packages at any point in system 3200. For example, in an embodiment, cross-cutter 2204 may be positioned in system 3200 after heat sink-to-substrate attacher 3204. Heat sink strip 2210 may be attached to a die-mounted substrate strip by heat sink-to-substrate attacher 3204, and cross-cutter 2204 may subsequently be used to singulate the substrate strip into separate substrates, simultaneously cutting heat sink strip 2210 into separate heat sinks.

### CONCLUSION

While various embodiments of the present invention have been described above, it should be understood that they have been presented by way of example only, and not limitation. It will be apparent to persons skilled in the relevant art that various changes in form and detail can be made therein without departing from the spirit and scope of the invention. Thus, the breadth and scope of the present invention should not be limited by any of the above-described exemplary embodiments, but should be defined only in accordance with the following claims and their equivalents

What is claimed is:

1. A method for assembling integrated circuit packages, comprising:
extruding a stock material through a die to form a heat sink strip having a cross-section defined by the die, said extruding comprising forming a recessed region in a first surface of the heat sink strip that extends along a length of the heat sink strip, and forming a plurality of fins in a second surface of the heat sink strip along the length of the heat sink strip; and
cross-cutting the heat sink strip to separate the heat sink strip into a plurality of heat sinks.

2. The method of claim 1, further comprising:
forming a plurality of cross-cuts in the second surface of the heat sink strip across a width of the heat sink strip such that each heat sink separated from the heat sink strip includes a plurality of rows of fins, each row of the plurality of rows including multiple fins.

3. The method of claim 1, further comprising:
forming a cavity in the recessed region of at least one heat sink of the plurality of heat sinks.

4. The method of claim 1, wherein said extruding further comprises:
forming a notch in a side surface of the heat sink strip that extends along the length of the heat sink strip.

5. The method of claim 1, wherein said forming a plurality of fins in a second surface of the heat sink strip along the length of the heat sink strip comprises:
forming a first fin that is located opposite the recessed region to be offset from a second fin adjacent to the first fin.

6. The method of claim 1, wherein said extruding further comprises:
forming a second plurality of fins in the recessed region that extends from the first surface of the heat sink strip and that is opposed to the first plurality of fins.

7. The method of claim 1, wherein said extruding further comprises:
forming first and second protruding portions separated by the recessed region and extending along the length of the heat sink strip to be offset from outer edges of the width of the heat sink strip.

8. The method of claim 1, further comprising:
forming a plurality of cross-cuts in the second surface of the heat sink strip across a width of the heat sink strip such that each heat sink separated from the heat sink strip includes a first post extending from a first corner of the heat sink, a second post extending from a second corner of the heat sink, a third post extending from a third corner of the heat sink, and a fourth post extending from a fourth corner of the heat sink.

9. The method of claim 8, further comprising:
forming a rectangular cavity in the recessed region of at least one heat sink of the plurality of heat sinks.

10. The method of claim 9, wherein said forming a rectangular cavity in the recessed region of at least one heat sink of the plurality of heat sinks comprises:
forming the cavity such that each corner of the cavity is adjacent to an inner corner of a corresponding one of the first, second, third, and fourth posts of the at least one heat sink.

11. The method of claim 9, wherein said forming a rectangular cavity in the recessed region of at least one heat sink of the plurality of heat sinks comprises:
forming the cavity to form a notch in each of the first, second, third, and fourth posts of the at least one heat sink.

12. The method of claim 8, wherein said forming a plurality of cross-cuts in the second surface of the heat sink strip comprises:
forming the plurality of cross-cuts to have a depth that is less than a depth of the recessed region.

13. An integrated circuit package, comprising:
a substrate having opposing first and second surfaces;
a flip chip integrated circuit die having opposing first and second surfaces, wherein the first surface of the die is mounted to the first surface of the substrate by a plurality of electrically conductive solder bumps; and
a heat sink having a first surface that includes a recessed region extending along a length of the heat sink in the first surface and that includes first and second supporting portions separated by the recessed region, wherein the first and second supporting portions are attached to the first surface of the substrate such that the die is positioned in the recessed region, and the second surface of the die is attached to a surface of the recessed region.

14. The integrated circuit package of claim 13, wherein the heat sink has a second surface that is opposed to the first surface of the heat sink, wherein the heat sink further includes a plurality of fins extending from the second surface.

15. The integrated circuit package of claim 14, wherein each fin extends along the length of the heat sink.

16. The integrated circuit package of claim 14, wherein the plurality of fins are formed in a plurality of rows, and each row of the plurality of rows includes multiple fins.

17. The integrated circuit package of claim 13, further comprising:
an electrical component mounted to the first surface of the substrate, the electrical component having a height greater than a height of the die;
wherein the surface of the recessed region includes a cavity, wherein a portion of the electrical component extends into the cavity.

18. The integrated circuit package of claim 13, wherein the heat sink includes a notch in a side surface of the heat sink that extends along the length of the heat sink.

19. The integrated circuit package of claim 14, wherein at least one fin of the plurality of fins is offset from an adjacent fin of the plurality of fins.

20. The integrated circuit package of claim 14, wherein the recessed region of the heat sink includes a second plurality of fins extending from the first surface of the heat sink and that is opposed to the first plurality of fins, wherein each fin of the second plurality of fins extends along the length of the heat sink.

21. The integrated circuit package of claim 13, wherein the first and second supporting portions are offset from outer edges of the width of the first surface of the heat sink.

22. The integrated circuit package of claim 13, further comprising:
a first post extending from the first supporting portion at a first corner of the heat sink;
a second post extending from the first supporting portion at a second corner of the heat sink;
a third post extending from the second supporting portion at a third corner of the heat sink; and
a fourth post extending from the second supporting portion at a fourth corner of the heat sink.

23. An integrated circuit package, comprising:
a substrate having opposing first and second surfaces;
a flip chip integrated circuit die having opposing first and second surfaces, wherein the first surface of the die is mounted to the first surface of the substrate by a plurality of electrically conductive solder bumps; and
a heat sink having a first surface that includes a first post extending from a first corner of the first surface of the heat sink, a second post extending from a second corner of the first surface of the heat sink, a third post extending from a third corner of the first surface of the heat sink, and a fourth post extending from a fourth corner of the first surface of the heat sink;
wherein the first, second, third, and fourth posts are attached to the first surface of the substrate such that the die is positioned within a perimeter formed by the first, second, third, and fourth posts, and the second surface of the die is attached to the first surface of the heat sink.

24. The integrated circuit package of claim 23, further comprising a rectangular cavity formed in the first surface of the heat sink, wherein the second surface of the die is attached to a surface of the cavity.

25. The integrated circuit package of claim 24, wherein each corner of the cavity is adjacent to an inner corner of a corresponding one of the first, second, third, and fourth posts.

26. The integrated circuit package of claim 24, wherein each corner of the cavity forms a notch in a corresponding one of the first, second, third, and fourth posts.

27. The integrated circuit package of claim 23, wherein a depth of the recessed region between the first and second posts is less than a depth of the recessed region between the first and third posts.

28. A system for assembling integrated circuit packages, comprising:
an extrusion press configured to extrude a stock material through a die to form a heat sink strip having a cross-section defined by the die, the die being configured to form a recessed region in a first surface of the heat sink strip along a length of the heat sink strip, and to form a plurality of fins in a second surface of the heat sink strip along the length of the heat sink strip; and
a cross-cutter configured to cross-cut the heat sink strip to separate the heat sink strip into a plurality of heat sinks.

29. The system of claim 28, wherein the cross-cutter is configured to form a plurality of cross-cuts in the second surface of the heat sink strip across a width of the heat sink strip such that each heat sink separated from the heat sink strip includes at least one of the plurality of cross-cuts across a width of the heat sink.
